(19) United States
(12) Patent Application Publication
(10) Pub. No.: US 2012/0236473 A1
(43) Pub. Date: Sep. 20, 2012

(54) ELECTRONIC DEVICE

(75) Inventors: ZHENG-HENG SUN, Tu-Cheng (TW); AN-GANG LIANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/080,615

(22) Filed: Apr. 5, 2011

(30) Foreign Application Priority Data
Mar. 18, 2011 (CN) 201110065331.X

(51) Int. Cl. H05K 5/00; B65D 63/00

(52) U.S. Cl. 361/679.01; 24/16 R

(57) ABSTRACT

An electronic device includes a chassis including a sidewall, a power supply mounted to an inner surface of the sidewall of the chassis, a power cord connected to the power supply, and a cable binding apparatus. The cable binding apparatus includes a first tie detachably mounted to the sidewall of the chassis, and a fixing member movably installed to the first tie. The fixing member includes a board. A second tie and a first fixing portion for fixing the power cord are formed at a side of the board; a second fixing portion for fixing the first tie is formed at the other side of the board opposite to first blocking portion.

### BACKGROUND

1. Technical Field

The present disclosure relates to an electronic device with cable binding apparatus.

2. Description of Related Art

Cable binding apparatuses are generally used to bind power cords to avoid the power cords from disconnecting disengaging from a power supply mounted in an inner surface of a sidewall of a chassis. In some cases, a cable tie binds a corresponding power cord extending through a sidewall of a chassis and is fixed to the power supply. However, when the power supply needs to be taken out of the chassis, the cable tie must be destroyed. Which is inconvenient, and the cable tie cannot be reused. In other cases, hooks are formed at the sidewall of the chassis for positioning the power cords. However, the power cords are only positioned by the hooks, and can still easily disconnected from the chassis.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of an electronic device; the electronic device includes a first tie and a fixing member.

FIG. 2 is an enlarged view of the first tie of FIG. 1, but viewed from another perspective.

FIG. 3 is an enlarged view of the fixing member of FIG. 1, but viewed from another perspective.

FIG. 4 is an assembled, isometric view of FIG. 1.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

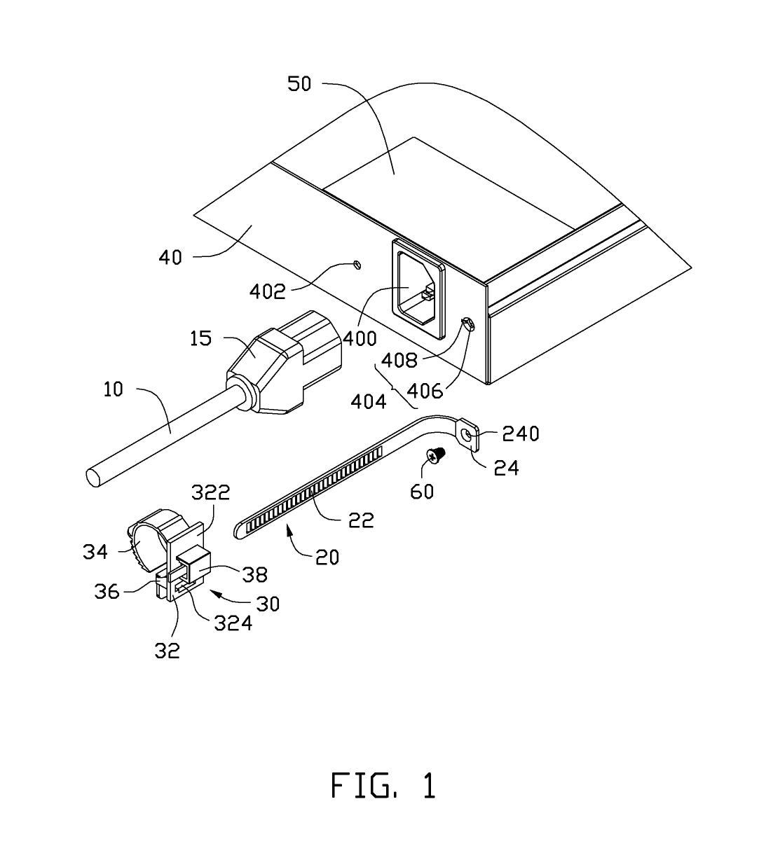

Referring to FIG. 1, an exemplary embodiment of an electronic device includes a chassis 40, a power supply 50 mounted in the chassis 40, a plug 15 with a power cord 10 extending from the power supply 50, and a binding apparatus. The power supply 50 includes a power jack 400 exposed through the chassis 40. The binding apparatus includes a first tie 20 and a fixing member 30.

The chassis 40 defines a first through hole 402 and a second through hole 404 therein, at opposite sides of the power jack 400. The second through hole 404 includes a tapered extension portion 406, and a substantially rectangular-shaped limiting portion 408 communicating with the extension portion 406. The power supply 50 defines two fixing holes (not shown) therein corresponding to the first through holes 402 and the extension 406 of the second through hole 404 of the chassis 40.

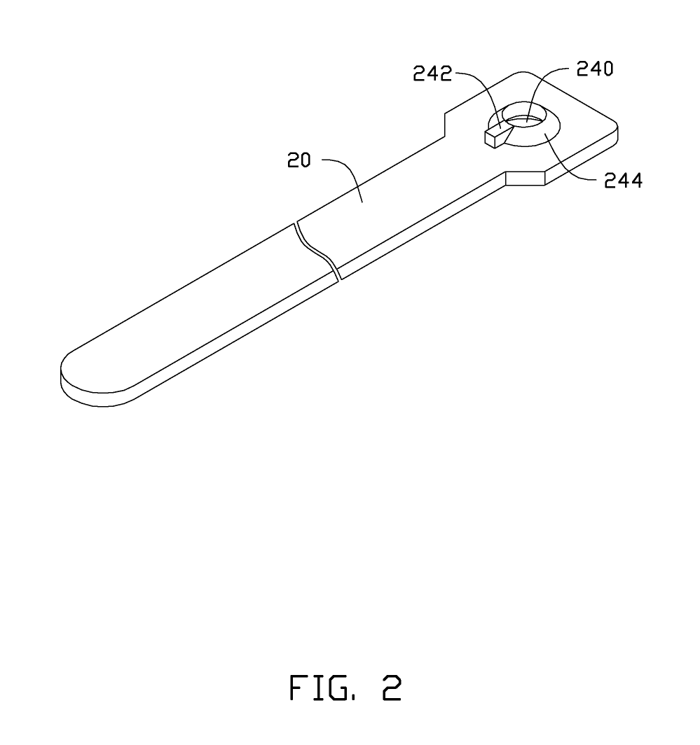

Referring to FIG. 2, a plurality of spaced slots 22 is longitudinally arranged in a side of the first tie 20. A fixing portion 24 extends from an end of the first tie 20. A through hole 240 is defined in the fixing portion 24. A tapered engaging portion 244 extends from a side of the fixing portion 24 opposite to the slots 22, arranged around the through hole 240. A substantially rectangular-shaped protrusion 242 extends from the fixing portion 24, connected to the engaging portion 244.

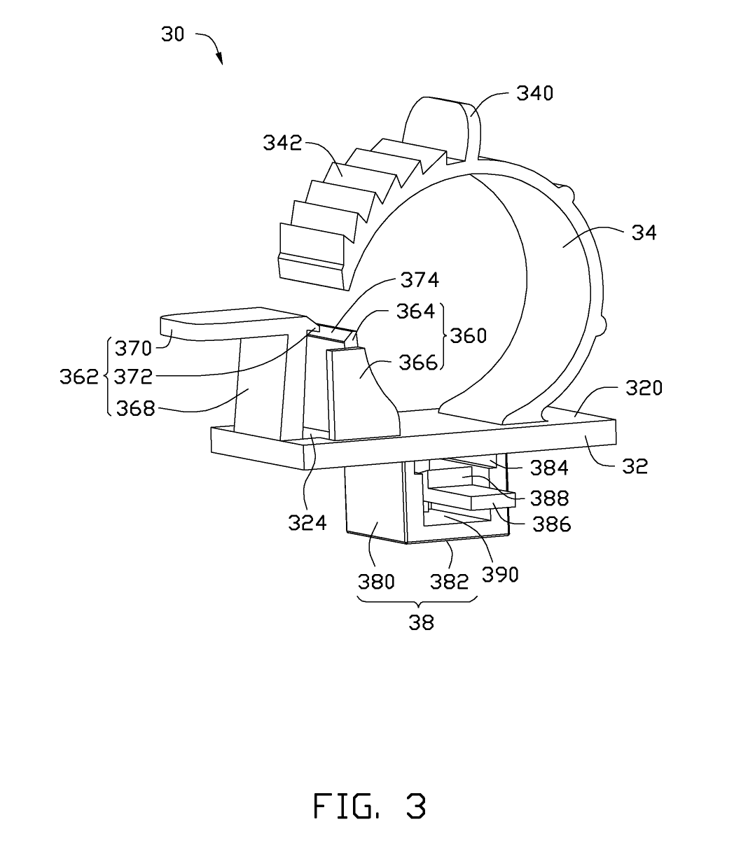

Referring to FIG. 3, the fixing member 30 includes a board 32, a second tie 34, a first fixing portion 36 (labeled in FIG. 1), and a second fixing portion 38. The second tie 34 is flexible.

The board 32 includes a first surface 320 and a second surface 322 opposite to each other. A through hole 324 is defined in the board 32, adjacent to a first end of the board 32.

The second tie 34 extends from a second end of the first surface 320 away from the through hole 324, bent toward the through hole 324. A plurality of first projections 342 and a first operation piece 340 extend from a side of the second tie 34, opposite to the through hole 324.

The first fixing portion 36 is formed at the first side 320 of the board 32, and includes a first blocking portion 360 and a substantially L-shaped second blocking portion 362. The first blocking portion 360 includes a slanted plate 364 extending from the first side 320 of the board 32, at a first side of the through hole 324 adjacent to the second tie 34 and two side plates 366 extending from the first side 320 of the board 32, at opposite ends of the through hole 324. The second blocking portion 362 includes an extension plate 368 extending from the first side 320 of the board 32, at a second side of the through hole 324 opposite to the slanted plate 364. A second operation piece 370 and a second projection 372 perpendicularly extend from a distal end of the extension plate 368 and away from each other. An opening 374 is defined between distal ends of the slanted plate 364 and the second projection 372.

The second fixing portion 38 includes two opposite blocking pieces 380 perpendicularly extending from the second surface 322 of the board 32, and a connection piece 382 is perpendicularly connected between distal ends of the blocking pieces 380. The board 32, the blocking pieces 380, and the connection piece 382 together bound a receiving space 390. A slide slot 384 is defined in an inner surface of each blocking piece 380 adjacent to the board 32. A substantially L-shaped third operation piece 386 extends from a first side of an inner surface of the connection piece 382, and extends out of the receiving space 390 from a second side of the inner surface of the connection piece 382. A third projection 388 protrudes from the third operation piece 386, facing the board 32.

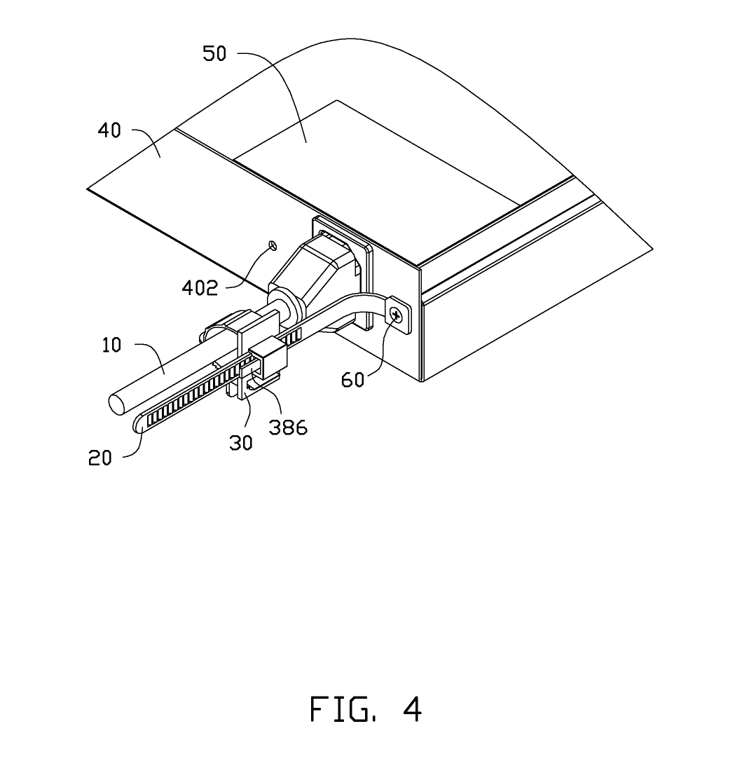

Referring to FIG. 4, in assembling the binding apparatus, the third operation piece 386 is deformed towards the connection piece 380. The first tie 20 extends through the receiving space 390 of the second fixing portion 38, and slidably engages in the slide slots 384, with the slots 22 of the first tie 20 facing the third operation piece 386. The third operation piece 386 is released and is restored, and the third projection 388 is engaged in one of the slots 22.

The engaging portion 244 and the protrusion 242 of the first tie 20 are respectively received in the extension portion 406 and the limiting portion 408 of the second through hole 404 of the chassis 40. A screw 60 extends through the through hole 240 of the first tie 20 and is engaged with the chassis 40, to fix the binding apparatus to the outer side of the chassis 40.

In use, the second tie 34 of the fixing member 30 fits about the power cord 10. The second operation piece 370 is deformed away from the first blocking portion 360, thereby expanding the opening 374. The distal end of the second tie 34 extends through the opening 374 and the through hole 324 of the board 32. The second operation piece 370 is released and is restored, and one of the first projections 342 of the second tie 34 is blocked by the second projection 372 of the second blocking portion 362.

In disengaging the power supply 50 from the chassis 40, the second operation piece 370 is deformed away from the first blocking portion 360 to expand the opening 374, and the first operation piece 340 is moved away from the through hole 324 of the board 32, for disengaging the power cord 10 from the binding apparatus.

In adjusting a position of the fixing member 30, the third operation piece 386 is deformed toward the connection piece 382, and the third projection 388 is disengaged from the corresponding slot 22. Therefore, the fixing member 30 can be moved relative to the first tie 20, to engage in another slot 22.

In this embodiment, the through hole 240 of the first tie 20 is a countersunk hole to receive a flat head of the screw 60.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. An electronic device, comprising:
a chassis;
a power supply mounted in the chassis, the power supply comprising a power jack exposed through the chassis;
a plug connected to the power jack, with a power cord extending out from the plug; and
a binding apparatus comprising a first tie mounted to an outer surface of the chassis, and a fixing member adjustably installed to the first tie, the fixing member comprising a board, a second tie and a first fixing portion formed at a first side of the board to cooperatively bind the power cord, and a second fixing portion formed at a second side of the board opposite to the first fixing portion to be adjustably fixed to the first tie.

2. The electronic device of claim 1, wherein a plurality of slots is longitudinally arranged in the first tie, the second blocking portion comprises two blocking pieces extending from the second side of the board and a connection piece connected between distal ends of the blocking portions, a substantially L-shaped operation piece extends from an inner surface of the connection piece, a projection protrudes from the operation piece to selectively engage in one of the slots of the first tie.

3. The electronic device of claim 2, wherein a slide slot is defined in an inner side of each blocking piece adjacent to the board, the first tie is slidably engaged in the slide slots.

4. The electronic device of claim 1, wherein the chassis defines a first hole at a side of the power jack, the first tie defines a second hole in an end, the first hole comprises a tapered extension portion and a limiting portion communicating with the extension portion, a tapered engaging portion and a protrusion protrude from an end of the first tie to be respectively received in the extension portion and the limiting portion of the first hole, a screw extends through the second hole of the first tie to engage in the first hole of the chassis.

5. The electronic device of claim 4, wherein the second through hole of the first tie is a countersink hole, for receiving a flathead of the screw.

6. The electronic device of claim 1, wherein the first fixing portion comprises a first blocking portion and a second blocking portion, an opening is defined between the first and second blocking portions, a first projection extends toward the opening from the second blocking portion, a plurality of second projections protrudes from a side of the second tie, the second tie extends through the opening and the board, with one of the second projections blocked by the first projection.

7. The electronic device of claim 6, wherein an operation piece is formed on the second tie, adjacent to the second projections.

8. The electronic device of claim 6, wherein the second blocking portion comprises an extension plate extending from the board, and an operation piece extending from the extension plate, away from the first projection.

9. A binding apparatus for cables, the binding apparatus comprising:
a first tie to be mounted to a chassis; and
a fixing member comprising a board, a second tie formed at a first side of the board to bind the cables, and a first fixing portion formed at a second side of the board opposite to the first fixing portion to be adjustably fixed to the first tie.

10. The binding apparatus of claim 9, wherein a plurality of slots is longitudinally arranges in the first tie, the first fixing portion comprises a projection to be selectively engaged with one of the plurality of slots of the first tie.

11. The binding apparatus of claim 10, wherein the first fixing portion further comprises two blocking pieces extending from the second side of the board and a connection piece connected between distal ends of the blocking pieces, an operation piece extends from an inner surface of the connection piece, wherein the projection extends from the operation piece toward the board.

12. The binding apparatus of claim 9, wherein the second tie is flexible, a second fixing portion is formed at the first side of the board, to fix the second tie after the second tie is bent.

13. The binding apparatus of claim 12, wherein the second fixing portion comprises a first projection, the second tie forms a plurality of second projections opposite to the board, the first projection is selectively engaged with one of the plurality of second projections.
